(19) United States
(12) Patent Application Publication
(10) Pub. No.: US 2024/0315043 A1
(43) Pub. Date: Sep. 19, 2024

(54) SEMICONDUCTOR MEMORY DEVICE AND METHOD OF MANUFACTURING THE SAME

(71) Applicant: Kioxia Corporation, Tokyo (JP)

(72) Inventor: Shosuke FUJII, Kuwana Mie (JP)

(21) Appl. No.: 18/593,989

(22) Filed: Mar. 4, 2024

(30) Foreign Application Priority Data
Mar. 13, 2023 (JP) 2023-039075

(51) Int. Cl. H10B 51/30

(52) U.S. Cl. CPC H10B 51/30

(57) ABSTRACT

A semiconductor memory device includes a ferroelectric memory transistor. The ferroelectric memory transistor includes a first conductive layer extending in a first direction and having a cylindrical shape and an upper surface that has a diameter R1, a first semiconductor layer extending in the first direction and having a cylindrical base portion in contact with the upper surface of the first conductive layer, the cylindrical base portion extending further in a radial direction than the upper surface of the first conductive layer such that a diameter R2 thereof is greater than the diameter R1, a ferroelectric layer extending in the first direction and surrounded by the first semiconductor layer, a second conductive layer extending in the first direction and surrounded by the ferroelectric layer, and a third conductive layer in contact with an outer periphery of the first semiconductor layer.

### CROSS-REFERENCE TO RELATED APPLICATION(S)

This application is based upon and claims the benefit of priority from Japanese Patent Application No. 2023-039075, filed Mar. 13, 2023, the entire contents of which are incorporated herein by reference.

### FIELD

Embodiments described herein relate generally to a semiconductor memory device and a method of manufacturing the semiconductor memory device.

### BACKGROUND

A ferroelectric memory has been attracting attention as a nonvolatile memory capable of high-speed operation. The ferroelectric memory uses the polarization reversal of the ferroelectric material to write data to a memory cell and to erase data from the memory cell.

### DESCRIPTION OF THE DRAWINGS

FIG. 1A is a cross-sectional view of a semiconductor memory device according to a comparative example.

FIG. 1B is a cross-sectional view taken along line I-I of FIG. 1A.

FIG. 1C is a cross-sectional view illustrating an operation of the semiconductor memory device according to the comparative example.

FIG. 2A is a cross-sectional view of a semiconductor memory device according to a first embodiment.

FIG. 2B is a cross-sectional view taken along line II-II of FIG. 2A.

FIG. 2C is an enlarged view of a vicinity of a source contact of FIG. 2A.

FIG. 2D is a cross-sectional view illustrating an operation of the semiconductor memory device according to the embodiment.

FIG. 3 is a circuit configuration diagram of a memory cell array of the semiconductor memory device according to the first embodiment.

FIG. 4A is a circuit block diagram of the memory cell array of the semiconductor memory device according to the first embodiment.

FIG. 4B is a top view of the memory cell array of the semiconductor memory device according to the first embodiment.

FIG. 5A is a circuit diagram of a write operation of the semiconductor memory device according to the first embodiment.

FIG. 5B is a circuit diagram of an erasing operation of the semiconductor memory device according to the first embodiment.

FIG. 5C is a circuit diagram of a read operation of the semiconductor memory device according to the first embodiment.

FIG. 5D is a diagram illustrating operation modes of the semiconductor memory device according to the first embodiment.

FIG. 6 is a cross-sectional view of a semiconductor memory device according to Modification Example 1 of the first embodiment.

FIG. 7 is a cross-sectional view of a semiconductor memory device according to Modification Example 2 of the first embodiment.

FIG. 8 is a cross-sectional view of a semiconductor memory device according to a second embodiment.

FIG. 9 is a cross-sectional view of a semiconductor memory device according to a third embodiment.

FIG. 10A is a circuit configuration diagram of a memory cell array of the semiconductor memory device according to the third embodiment.

FIG. 10B is a top view of the memory cell array of the semiconductor memory device according to the third embodiment.

FIG. 11A is a circuit diagram of a write operation of the semiconductor memory device according to the third embodiment.

FIG. 11B is a circuit diagram of a read operation of the semiconductor memory device according to the third embodiment.

FIG. 11C is a circuit diagram of a hold operation of the semiconductor memory device according to the third embodiment.

FIG. 11D is a diagram illustrating operation modes of the semiconductor memory device according to the third embodiment.

FIG. 12 is a cross-sectional view of a semiconductor memory device according to a fourth embodiment.

FIG. 13 is a cross-sectional view of a semiconductor memory device according to a modification example of the fourth embodiment.

FIG. 14 is a circuit block diagram of a memory cell array of the semiconductor memory device according to the fourth embodiment.

FIGS. 15A and 15B are cross-sectional and top views depicting a step in a method of manufacturing a semiconductor memory device having a source connection configuration.

FIG. 15C is a diagram illustrating a size relationship between layers of the semiconductor memory device having the source connection configuration.

FIGS. 16A and 16B, 17A and 17B, 18A and 18B, 19A and 19B, 20A and 20B, and 21A and 21B are cross-sectional and top views depicting additional steps in the method of manufacturing the semiconductor memory device having the source connection configuration.

FIGS. 22A and 22B, 23A and 23B, 24A and 24B, 25A and 25B, 26A and 26B, 27A and 27B, 28A and 28B, 29A and 29B, and 30A and 30B are cross-sectional and top views depicting steps in a method of manufacturing a semiconductor memory device having a gate connection configuration.

### DETAILED DESCRIPTION

Embodiments provide a semiconductor memory device and a method of manufacturing the semiconductor memory device that has an ferroelectric layer to which an electric field can be efficiently applied, reduces an operating voltage, stabilizes spontaneous polarization with a low coupling ratio, and improves storing characteristics.

In general, according to one embodiment, a semiconductor memory device of the embodiments includes a ferroelectric memory transistor. The ferroelectric memory transistor includes a first conductive layer extending in a first direction and having a cylindrical shape and an upper surface that has a diameter R1, a first semiconductor layer extending in the first direction and having a cylindrical base portion in contact with the upper surface of the first conductive layer, the cylindrical base portion extending further in a radial direction than the upper surface of the first conductive layer such that a diameter R2 thereof is greater than the diameter R1, a ferroelectric layer extending in the first direction and surrounded by the first semiconductor layer, a second conductive layer extending in the first direction and surrounded by and the ferroelectric layer, and a third conductive layer in contact with an outer periphery of in the first semiconductor layer.

Hereinafter, embodiments will be described with reference to the drawings. The relationship between the thickness and the plane dimensions of each element shown in the drawings, the ratio between the thicknesses of each element, and the like may differ from those of the actual product. An up-down direction may differ from an up-down direction based on gravity. In addition, in the embodiments, substantially the same elements will be given the same reference numerals, and the description thereof will be omitted as appropriate.

In the present specification, the term “connect” includes not only a physical connection but also an electrical connection, and includes not only a direct connection but also an indirect connection, unless otherwise specified.

In the following description, a direction perpendicular to a substrate surface extending in an XY plane is defined as a Z direction, a direction that is orthogonal to the Z direction and is an extension direction of a bit line BL is defined as an X direction, and a direction that is perpendicular to the Z direction, non-parallel to the X direction, and is an extension direction of a word line WL is defined as a Y direction. It should be noted that these directions are examples. The directions may be changed as appropriate depending on the arrangement of the pattern. Further, the substrate may include an insulating substrate, a semiconductor substrate, a substrate in which an electrode layer is embedded into an insulating substrate, and the like. Furthermore, the substrate may be a substrate in which a semiconductor element including an N-channel metal oxide gate semiconductor (MOS) field effect transistor, a P-channel MOS field effect transistor, and a complementary MOS (CMOS) field effect transistor is disposed.

In addition, in the following description, a memory cell array may be simply denoted by a semiconductor memory device.

The semiconductor memory device according to the embodiment is a ferroelectric memory having a ferroelectric transistor (ferroelectric field effect transistor (FeFET)) and has a memory cell array. In the semiconductor memory device according to the embodiment, circuit forms include a 1T-1FeFET circuit form, a 2T-1FeFET circuit form, a 3T (2T+1FeFET) circuit form, and the like. A 1FeFET cell circuit type in which the memory cell is a FeFET is also included. In addition, a memory cell in which the FeFET has a metal ferroelectric semiconductor (MFS) structure and a metal ferroelectric insulator metal insulator semiconductor (MFMIS) structure is also included. Further, the 1T-1FeFET circuit includes a source connection type in which the channel of a 1T select transistor and the source of the FeFET are connected to each other, and a gate connection type in which the channel of the 1T select transistor and the gate of the FeFET are connected to each other. Further, a connection type in which the source connection type and the gate connection type are combined is also included.

### Gate-All-Around Structure

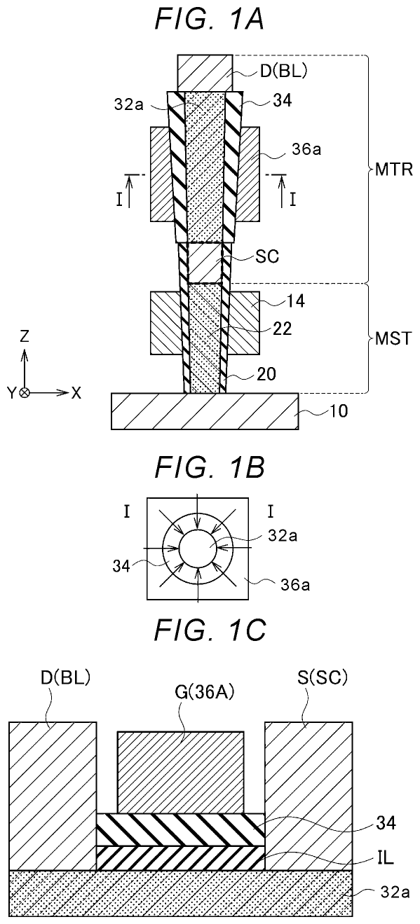

FIG. 1A is a cross-sectional view of a semiconductor memory device according to a comparative example.

The semiconductor memory device according to the comparative example includes a ferroelectric memory MTR as shown in FIG. 1A. The ferroelectric memory MTR includes a FeFET. The ferroelectric memory MTR includes a source contact SC, a semiconductor layer 32a in contact with the source contact SC and extending in the Z direction, a ferroelectric layer 34 in contact with the semiconductor layer 32a, and a conductive layer 36a in contact with the ferroelectric layer 34.

In addition, the semiconductor memory device according to the comparative example includes a select transistor MST as shown in FIG. 1A. The select transistor MST includes a semiconductor layer 22 extending in the Z direction, an insulating film 20 serving as a gate insulating layer in contact with the semiconductor layer 22, and a conductive layer 14 in contact with the insulating film 20 and serving as a select gate line extending in the Y direction perpendicular to the Z direction. The semiconductor layer 22 and the source contact SC serving as a source electrode of the ferroelectric memory MTR are in contact with each other.

FIG. 1B is a cross-sectional view taken along line I-I of FIG. 1A. As shown in FIGS. 1A and 1B, the semiconductor memory device according to the comparative example has a so-called surrounding gate transistor (SGT) structure in which the conductive layer 36a serving as the gate electrode of the ferroelectric memory MTR surrounds the semiconductor layer 32a serving as a channel. The SGT structure is also referred to as a gate-all-around structure. In the semiconductor memory device according to the comparative example, an electric field is applied from the conductive layer 36a toward the semiconductor layer 32a as indicated by arrows in FIG. 1B.

FIG. 1C is a cross-sectional view illustrating the operation of the semiconductor memory device according to the comparative example. FIG. 1C shows the ferroelectric memory MTR modeled as a horizontal structure. In the semiconductor memory device according to the comparative example, a drain electrode D (BL) connected to a bit line BL and a source electrode S(SC) connected to the source contact SC are connected to the semiconductor layer 32a. In addition, a gate electrode G (36a) is disposed between the drain electrode D (BL) and the source electrode S (SC). The gate electrode G (36a) and the semiconductor layer 32a are disposed with the ferroelectric layer 34 therebetween. Here, an insulating layer IL called an interlayer is sandwiched between the ferroelectric layer 34 and the semiconductor layer 32a. As shown in FIG. 1C, the ferroelectric memory MTR of the semiconductor memory device according to the comparative example has an MFS structure including a stacked structure of the conductive layer 36a/ferroelectric layer 34/semiconductor layer 32a. In the semiconductor memory device according to the comparative example, a coupling ratio between the gate electrode G (36a) and the semiconductor layer 32a is likely to be large due to the structure thereof. When the coupling ratio is large, the reduction polarization field component becomes large, the spontaneous polarization cannot be maintained, and the PV polarization characteristic representing the relationship between a polarization charge amount P of the ferroelectric layer 34 and a voltage V to be applied is likely to enter a minor loop state, which is a partial polarization state. Therefore, the data storing characteristics also deteriorate. In addition, in the semiconductor memory device according to the comparative example, since the fringing electric field from the gate electrode G (36a) is less likely to be applied to a fringe portion, which is an end portion of the ferroelectric layer 34, the polarization reversal of the ferroelectric layer 34 is less likely to occur.

### First Embodiment

### Channel-All-Around Structure

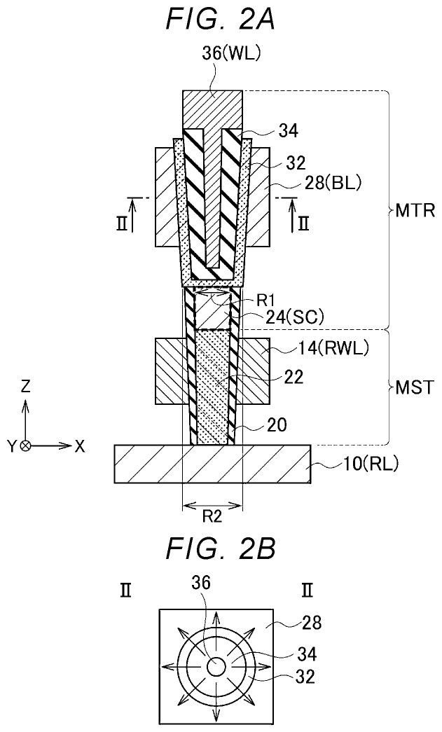

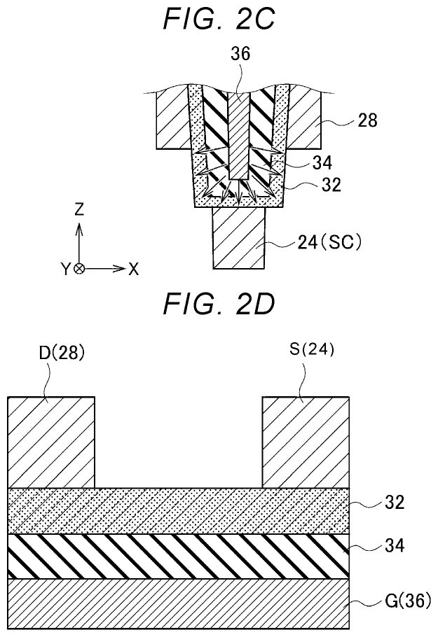

FIG. 2A is a cross-sectional view of a semiconductor memory device according to a first embodiment.

The semiconductor memory device according to the first embodiment includes the ferroelectric memory MTR as shown in FIG. 2A. The ferroelectric memory MTR includes a FeFET. The ferroelectric memory MTR includes the conductive layer 24 extending in the Z direction and having a cylindrical shape, a semiconductor layer 32 in contact with the conductive layer 24 and extending in a radial direction of the cylindrical shape and in the Z direction, the ferroelectric layer 34 in contact with the semiconductor layer 32, a conductive layer 36 in contact with the ferroelectric layer 34, and a conductive layer 28 extending in the X direction perpendicular to the Z direction and in contact with a plane intersecting a radial direction of a region extending in the Z direction in the semiconductor layer 32. Here, the radial diameter R2 of the semiconductor layer 32 is larger than the radial diameter R1 of the conductive layer 24.

In addition, the semiconductor memory device according to the first embodiment includes the select transistor MST as shown in FIG. 2A. The select transistor MST includes the semiconductor layer 22 extending in the Z direction, the insulating film 20 serving as the gate insulating layer in contact with the semiconductor layer 22, and the conductive layer 14 in contact with the insulating film 20 and serving as a select gate line extending in the Y direction perpendicular to the Z direction, and the semiconductor layer 22 and the conductive layer 24 (SC) serving as the source electrode of the ferroelectric memory MTR are in contact with each other.

FIG. 2B is a cross-sectional view taken along line II-II of FIG. 2A. As shown in FIGS. 2A and 2B, the semiconductor memory device according to the first embodiment has a channel-all-around structure in which the ferroelectric layer 34 and the semiconductor layer (channel) 32 surround the conductive layer 36 serving as the gate electrode of the ferroelectric memory MTR. In the semiconductor memory device according to the embodiment, an electric field is applied from the conductive layer 36 to the conductive layer 28 as indicated by arrows in FIG. 2B.

FIG. 2C is an enlarged view of the vicinity of the conductive layer 24 (SC) serving as the source contact SC of FIG. 2A. In the semiconductor memory device according to the embodiment, since the ferroelectric layer 34 and the semiconductor layer 32 surround the conductive layer 36 serving as the gate electrode, an electric field is also applied from the conductive layer 36 toward the semiconductor layer 32 in the vicinity of the conductive layer 24 (SC) serving as the source contact SC, as indicated by arrows in FIG. 2C.

FIG. 2D is a cross-sectional view illustrating the operation of the semiconductor memory device according to the first embodiment. FIG. 2D shows the ferroelectric memory MTR modeled as a horizontal structure. In the semiconductor memory device according to the first embodiment, the drain electrode D (28) connected to the bit line BL and the source electrode S (24) connected to the source contact SC are connected to the semiconductor layer 32. The gate electrode G (36) and the semiconductor layer 32 are disposed with the ferroelectric layer 34 therebetween. As shown in FIG. 2D, the ferroelectric memory MTR of the semiconductor memory device according to the first embodiment includes an MFS structure including a stacked structure of the conductive layer 36/ferroelectric layer 34/semiconductor layer 32.

In the ferroelectric memory MTR of the semiconductor memory device according to the first embodiment, the coupling ratio between the gate electrode G (36) and the semiconductor layer 32 is likely to be small due to the structure thereof. When the coupling ratio is small, the reduction polarization field becomes small, the spontaneous polarization can be maintained, and the PV polarization characteristic of the ferroelectric layer 34 exhibits a widely expanded loop state. Therefore, the data storing characteristics are also stabilized.

In the semiconductor memory device according to the first embodiment, since the ferroelectric layer 34 and the semiconductor layer 32 surround the conductive layer 36 serving as the gate electrode, the electric field from the gate electrode G (36) is likely to be applied to the entire ferroelectric layer 34. Therefore, the polarization reversal of the ferroelectric layer 34 is also likely to occur, and the operational stability is ensured.

The semiconductor memory device according to the first embodiment is expected to achieve a reduction in operating voltage because the electric field can be efficiently applied to the ferroelectric layer 34 as compared to the comparative example, and the storing characteristics can also be improved because the coupling ratio is small and the spontaneous polarization is stabilized.

The ferroelectric memory MTR of the semiconductor memory device according to the first embodiment has a channel-all-around structure and has a structure in which the gate electrode is embedded into a channel region through the ferroelectric layer. Therefore, the coupling ratio can be reduced, and spontaneous polarization can be stabilized. In addition, since the gate voltage is applied to the entire ferroelectric layer, the ferroelectric layer is prone to reversal.

The conductive layer 24 is the source electrode of the ferroelectric memory MTR. The conductive layer 36 is the gate electrode of the ferroelectric memory MTR and is connected to the word line WL extending in the Y direction. The conductive layer 28 is the drain electrode of the ferroelectric memory MTR and is connected to the bit line BL extending in the X direction. A conductive layer 10 is connected to a read line RL extending in the Y direction.

The conductive layer 10, the conductive layer 24, the conductive layer 36, and the conductive layer 28 contain at least one material selected from the group consisting of tungsten (W), titanium (Ti), titanium nitride (TiN), molybdenum (Mo), cobalt (Co), tantalum (Ta), ruthenium (Ru), iridium (Ir), and impurity-doped silicon.

The semiconductor layer 32 includes an oxide semiconductor layer. The oxide semiconductor layer contains at least one element selected from the group consisting of indium (In), gallium (Ga), zinc (Zn), tin (Sn), tungsten (W), and titanium (Ti).

The oxide semiconductor layer may contain indium oxide and gallium oxide, indium oxide and zinc oxide, or indium oxide and tin oxide. That is, the semiconductor layer 32 can be formed of InGaZnO, InO, or the like. In addition, the semiconductor layer 32 can be formed of titanium oxide (TiO), tungsten oxide (WO), or the like.

The ferroelectric layer 34 includes an oxide layer containing hafnium (Hf) and zirconium (Zr) as main components. The ferroelectric layer 34 may include an HfZrOx film. In addition, the ferroelectric layer 34 may have a stacked structure of ZrO₂/HfZrO₂/ZrO₂, ZrO₂/HfO₂/ZrO₂, or the like. In addition, the ferroelectric layer 34 may be a perovskite-type ferroelectric layer such as PZT or BTO.

The insulating film 20 contains at least one element selected from the group consisting of silicon (Si), silicon nitride (SiN), germanium (Ge), aluminum (Al), hafnium (Hf), zirconium (Zr), lanthanum (La), niobium (Nb), yttrium (Y), tantalum (Ta), vanadium (V), and magnesium (Mg), and oxygen.

### Memory Cell Array

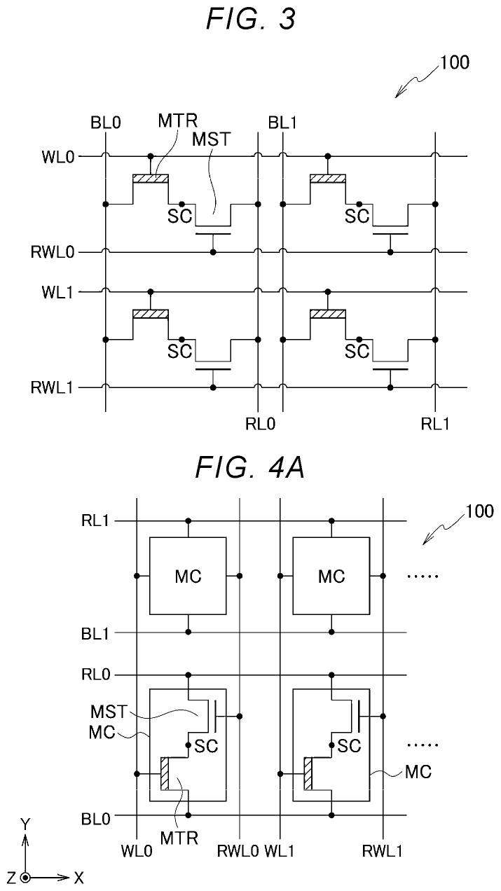

FIG. 3 is a circuit configuration diagram of a memory cell array 100 of the semiconductor memory device according to the first embodiment. The memory cell of the semiconductor memory device according to the first embodiment has the 1T-1FeFET circuit and has a source connection configuration in which the source of the ferroelectric memory MTR is connected to the channel of the select transistor MST. The drain of the ferroelectric memory MTR is connected to bit lines BL0, BL1, . . . , the gate of the ferroelectric memory MTR is connected to word lines WL0, WL1, . . . , the drain of the select transistor MST is connected to read lines RL0, RL1, . . . , and the gate of the select transistor MST is connected to read word lines RWL0, RWL1, . . .

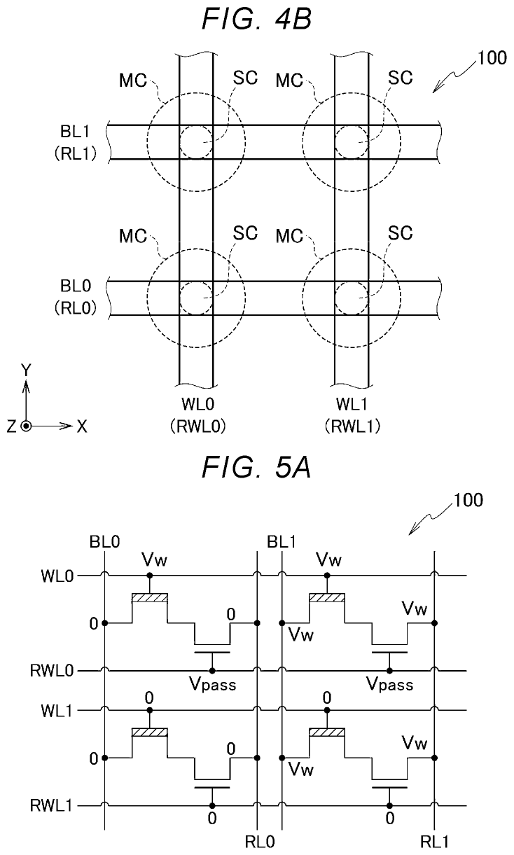

FIG. 4A is a circuit block diagram of the memory cell array 100 of the semiconductor memory device according to the first embodiment. In a memory cell MC, the ferroelectric memory MTR and the select transistor MST are connected to each other through the source contact SC, and such memory cells MC are two-dimensionally disposed in the X direction and the Y direction.

FIG. 4B is a schematic top view of the memory cell array 100 of the semiconductor memory device according to the first embodiment. The bit lines BL0 and BL1 and the read lines RL0 and RL1 overlap each other vertically in the Z direction. In addition, the word lines WL0 and WL1 and the read word lines RWL0 and RWL1 also overlap each other vertically in the Z direction. The memory cell MC and the source contact SC are disposed at an intersection portion between the bit lines BL0 and BL1 and the word lines WL0 and WL1.

### Operation Modes of First Embodiment

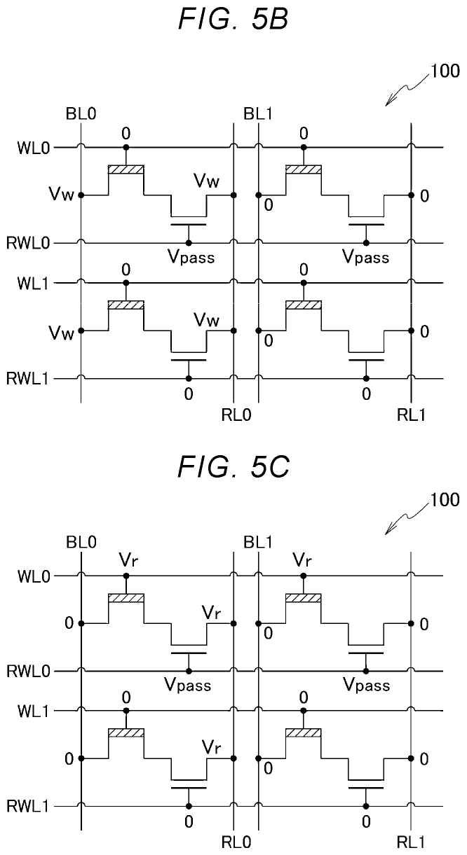

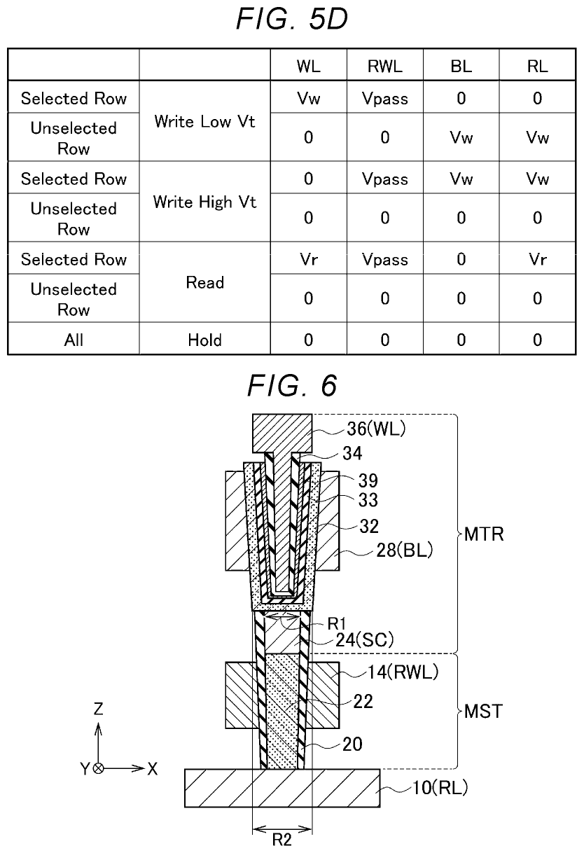

FIG. 5A is a circuit diagram of a write operation. FIG. 5B is a circuit diagram of an erasing operation. FIG. 5C is a circuit diagram of a read operation. FIG. 5D is a diagram illustrating operation modes.

During the write operation, a voltage is applied to each line as shown in FIG. 5A in accordance with the operation mode of FIG. 5D. In the example of FIG. 5A, a case where the write operation is executed on the memory cell MC connected to the word line WL0 and the read word line RWL0 between the bit line BL0 and the read line RL0, and the write operation is not performed on the other memory cells is shown. That is, a write voltage Vw is applied to the word line WL0, a voltage Vpass is applied to the read word line RWL0, 0 V is applied to the word line WL1, and 0 V is applied to the read word line RWL1.0 V is applied to the bit line BL0, 0 V is applied to the read line RL0, the write voltage Vw is applied to the bit line BL1, and a voltage equal to the write voltage Vw is applied to the read line RL1.

During the erasing operation, a voltage is applied to each line as shown in FIG. 5B in accordance with the operation mode of FIG. 5D. In the example of FIG. 5B, a case where the erasing operation is executed on the memory cell MC connected to the word line WL0 and the read word line RWL0 between the bit line BL0 and the read line RL0, and the erasing operation is not performed on the other memory cells is shown. That is, 0 V is applied to the word line WL0, the voltage Vpass is applied to the read word line RWL0, 0 V is applied to the word line WL1, and 0 V is applied to the read word line RWL1. A voltage equal to the write voltage Vw is applied to the bit line BL0, a voltage equal to the write voltage Vw is applied to the read line RL0, 0 V is applied to the bit line BL1, and 0 V is applied to the read line RL0.

During the read operation, a voltage is applied to each line as shown in FIG. 5C in accordance with the operation mode of FIG. 5D. In the example of FIG. 5C, a read voltage Vr is applied to the word line WL0, the voltage Vpass is applied to the read word line RWL0, 0 V is applied to the word line WL1, and 0 V is applied to the read word line RWL1.0 V is applied to the bit line BL0, the read voltage Vr is applied to the read line RL0, 0 V is applied to the bit line BL1, and 0 V is applied to the read line RL1.

### Modification Example 1 of First Embodiment

As shown in FIG. 6, the semiconductor memory device according to Modification Example 1 of the first embodiment has an MFMIS structure including a stacked structure of the conductive layer 36/ferroelectric layer 34/conductive layer 39/insulating layer 33/semiconductor layer 32.

A semiconductor memory device according to Modification Example 1 of the first embodiment includes the ferroelectric memory MTR. As shown in FIG. 6, the ferroelectric memory MTR further includes the conductive layer 39 and the insulating layer 33 in a stacked structure between the ferroelectric layer 34 and the semiconductor layer 32. That is, the conductive layer 39 is provided between the ferroelectric layer 34 and the semiconductor layer 32 and is in contact with the ferroelectric layer 34, and the insulating layer 33 is provided between the conductive layer 39 and the semiconductor layer 32 and is in contact with the semiconductor layer 32. Other configurations are the same as those in the first embodiment.

The MFMIS structure has the stacked structure of the conductive layer 39 and the insulating layer 33, so that the electric field can be efficiently applied to the ferroelectric layer 34 as compared with the MFS structure of the first embodiment. Therefore, the coupling ratio can be reduced, and the stability of spontaneous polarization can be increased. Further, since the MFMIS structure can efficiently apply the electric field to the ferroelectric layer 34, a memory window MW can be widened, the storing characteristics can be improved, and the reliability can be increased.

### Modification Example 2 of First Embodiment

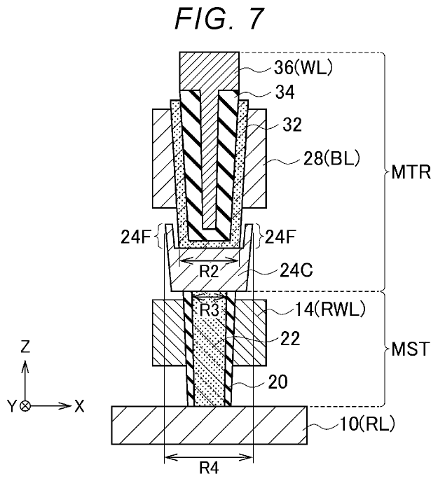

FIG. 7 is a cross-sectional view of a semiconductor memory device according to Modification Example 2 of the first embodiment.

As shown in FIG. 7, the semiconductor memory device according to Modification Example 2 of the first embodiment includes the ferroelectric memory MTR. The ferroelectric memory MTR includes a conductive layer 24C extending in the Z direction and having a cylindrical shape, the semiconductor layer 32 in contact with the conductive layer 24C and extending in the radial direction of the cylindrical shape and in the Z direction, the ferroelectric layer 34 in contact with the semiconductor layer 32, the conductive layer 36 in contact with the ferroelectric layer 34, and the conductive layer 28 extending in the X direction perpendicular to the Z direction and in contact with a plane intersecting the radial direction of the region extending in the Z direction in the semiconductor layer 32.

In addition, as shown in FIG. 7, the semiconductor memory device according to Modification Example 2 of the first embodiment includes the select transistor MST. The select transistor MST includes the semiconductor layer 22 extending in the Z direction, the insulating film 20 serving as the gate insulating layer in contact with the semiconductor layer 22, and the conductive layer 14 in contact with the insulating film 20 and serving as the select gate line RWL extending in the Y direction perpendicular to the Z direction. The semiconductor layer 22 and the conductive layer 24C serving as the source electrode of the ferroelectric memory MTR are in contact with each other.

The semiconductor memory device according to Modification Example 2 of the first embodiment includes a conductive layer 24F provided around the semiconductor layer 32 serving as the channel of the ferroelectric memory MTR and having a generally cylindrical plate structure surrounding a part of the semiconductor layer 32. The conductive layer 24F is connected to the conductive layer 24C. The conductive layer 24F is formed of the same material as that of the conductive layer 24C.

Here, the radial diameter R2 of the semiconductor layer 32 is larger than a radial diameter R3 of the semiconductor layer 22. A radial diameter R4 of the conductive layer 24F having a generally cylindrical plate structure is larger than the radial diameter R2 of the semiconductor layer 32. Other configurations are the same as those in the first embodiment.

In the semiconductor memory device according to Modification Example 2 of the first embodiment, the density of electric field lines generated by the electric field applied from the conductive layer 36 serving as the gate electrode of the ferroelectric memory MTR toward the conductive layer 24C serving as the source electrode of the select transistor MST is increased by the arrangement of the conductive layer 24F having a generally cylindrical plate structure. During the erasing operation, the semiconductor layer 32 is substantially depleted, but the erasing operation of the ferroelectric memory MTR can be efficiently performed as compared with a structure in which the conductive layer 24F is not provided, because the density of electric field lines generated by the applied electric field is high due to the effect of the arrangement of the conductive layer 24F.

### Second Embodiment: Two-Layer Stack

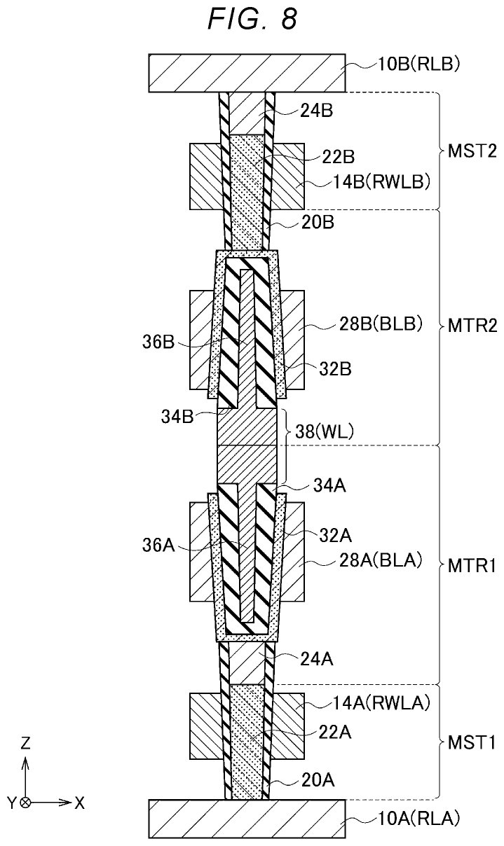

FIG. 8 is a cross-sectional view of a semiconductor memory device according to a second embodiment.

As shown in FIG. 8, the semiconductor memory device according to the second embodiment has a structure in which two semiconductor memory devices according to the first embodiment are stacked in the Z direction.

The semiconductor memory device according to the second embodiment includes a ferroelectric memory MTR1, a select transistor MST1, a ferroelectric memory MTR2, and a select transistor MST2.

The ferroelectric memory MTR1 includes a conductive layer 24A extending in the Z direction and having a cylindrical shape, the semiconductor layer 32A in contact with the conductive layer 24A and extending in the radial direction of the cylindrical shape and in the Z direction, a ferroelectric layer 34A in contact with the semiconductor layer 32A, a conductive layer 36A in contact with the ferroelectric layer 34A, and a conductive layer 28A in contact with a plane intersecting the radial direction of the region extending in the Z direction in the semiconductor layer 32A. The conductive layer 28A is connected to a bit line BLA extending in the X direction perpendicular to the Z direction.

The select transistor MST1 includes a semiconductor layer 22A extending in the Z direction, an insulating film 20A serving as a gate insulating layer in contact with the semiconductor layer 22A, and a conductive layer 14A in contact with the insulating film 20A and serving as a select gate line RWLA extending in the Y direction perpendicular to the Z direction.

The ferroelectric memory MTR2 includes a semiconductor layer 32B having a cylindrical shape and extending in the radial direction of the cylindrical shape and in the Z direction, a ferroelectric layer 34B in contact with the semiconductor layer 32B, a conductive layer 36B in contact with the ferroelectric layer 34B, and a conductive layer 28B in contact with a plane intersecting with a radial direction of a region extending in the Z direction in the semiconductor layer 32B. The conductive layer 28B is connected to a bit line BLB extending in the X direction.

The select transistor MST2 includes a semiconductor layer 22B extending in the Z direction, an insulating film 20B serving as a gate insulating layer in contact with the semiconductor layer 22B, and a conductive layer 14B in contact with the insulating film 20B and serving as a select gate line RWLB extending in the Y direction perpendicular to the Z direction.

The semiconductor layer 22A of the select transistor MST1 and the conductive layer 24A serving as the source electrode of the ferroelectric memory MTR are in contact with each other. The semiconductor layer 22B of the select transistor MST2 is in contact with the semiconductor layer 32B of the ferroelectric memory MTR2. The semiconductor layer 22A of the select transistor MST1 is also in contact with a conductive layer 10A serving as a read line RLA. The semiconductor layer 22B of the select transistor MST2 is also in contact with a conductive layer 10B serving as a read line RLB through a conductive layer 24B. The conductive layer 36A of the ferroelectric memory MTR1 and the conductive layer 36B of the ferroelectric memory MTR2 are connected to a conductive layer 38 serving as the word line WL.

Since the semiconductor memory device according to the second embodiment has a structure in which two semiconductor memory devices according to the first embodiment are stacked in the Z direction as shown in FIG. 8, the degree of integration can be increased. Other configurations are the same as those of the semiconductor memory device according to the first embodiment.

### Third Embodiment: Gate Connection Structure

In a semiconductor memory device according to a third embodiment, the ferroelectric memory MTR has an MFS structure. That is, the ferroelectric memory MTR has a stacked structure of the conductive layer 36/ferroelectric layer 34/semiconductor layer 32. A memory cell of the semiconductor memory device according to the third embodiment has the 1T-1FeFET circuit structure and has a gate connection configuration in which the gate of the ferroelectric memory MTR is connected to the channel of the select transistor MST.

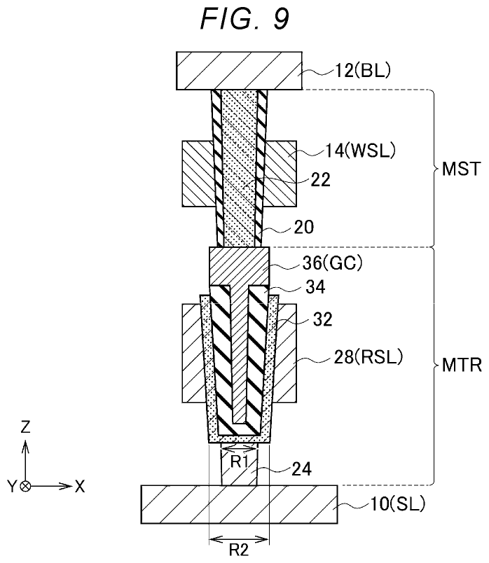

FIG. 9 is a cross-sectional view of the semiconductor memory device according to the third embodiment.

As shown in FIG. 9, the semiconductor memory device according to the third embodiment includes the ferroelectric memory MTR. The ferroelectric memory MTR includes the conductive layer 24 extending in the Z direction and having a cylindrical shape, the semiconductor layer 32 in contact with the conductive layer 24 and extending in the radial direction of the cylindrical shape and in the Z direction, the ferroelectric layer 34 in contact with the semiconductor layer 32, the conductive layer 36 in contact with the ferroelectric layer 34, and the conductive layer 28 serving as a read select line RSL extending in the X direction perpendicular to the Z direction and in contact with a plane intersecting the radial direction of a region extending in the Z direction in the semiconductor layer 32. Here, the radial diameter R2 of the semiconductor layer 32 is larger than the radial diameter R1 of the conductive layer 24.

In addition, the semiconductor memory device according to the third embodiment includes the select transistor MST as shown in FIG. 9. The select transistor MST includes the semiconductor layer 22 extending in the Z direction, a conductive layer 12 in contact with the semiconductor layer 22 and serving as the bit line BL, the insulating film 20 serving as the gate insulating layer in contact with the semiconductor layer 22, and the conductive layer 14 in contact with the insulating film 20 and serving as a word select line WSL. Here, the semiconductor layer 22 is connected to the conductive layer 36 serving as the gate electrode of the ferroelectric memory MTR.

The conductive layer 24 is the source electrode of the ferroelectric memory MTR and is connected to the conductive layer 10. The conductive layer 10 is connected to a sense line SL extending in the Y direction. The conductive layer 36 is the gate electrode of the ferroelectric memory MTR and is connected to a gate contact GC connected to the semiconductor layer 22 of the select transistor MST. The conductive layer 28 is the drain electrode of the ferroelectric memory MTR and is connected to the read select line RSL extending in the X direction. The conductive layer 14 is the gate electrode of the select transistor MST and is connected to the word select line WSL extending in the X direction.

The gate connection structure has a connection form between the ferroelectric memory MTR and the select transistor MST different from the source connection structure. Other configurations are the same as those in the first embodiment.

### Memory Cell Array

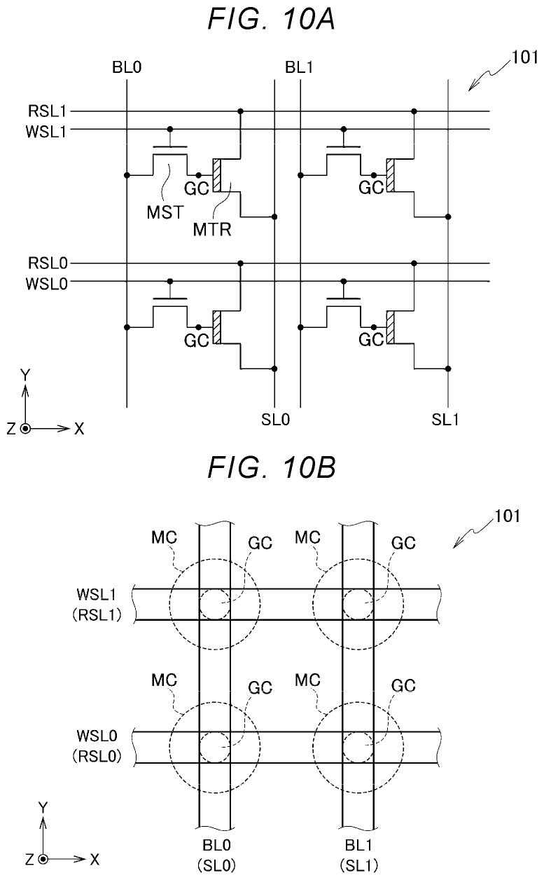

FIG. 10A is a circuit configuration diagram of a memory cell array 101 of the semiconductor memory device according to the third embodiment. A memory cell of the semiconductor memory device according to the third embodiment has the 1T-1FeFET circuit structure and has a gate connection configuration in which the gate of the ferroelectric memory MTR is connected to the channel of the select transistor MST. The drain of the select transistor MST is connected to the bit lines BL0, BL1, . . . , the gate of the select transistor MST is connected to the word select lines WSL0, WSL1, . . . , the drain of the ferroelectric memory MTR is connected to the read select lines RSL0, RSL1, . . . , and the source of the ferroelectric memory MTR is connected to the sense lines SL0, SL1, . . . .

Although the circuit block diagram of the memory cell array 101 of the semiconductor memory device according to the third embodiment is omitted, in the memory cell MC, the ferroelectric memory MTR and the select transistor MST are connected to each other through the gate contact GC, and such memory cells MC are two-dimensionally disposed in the X direction and the Y direction.

FIG. 10B is a schematic top view of the memory cell array 101 of the semiconductor memory device according to the third embodiment. The bit lines BL0 and BL1 and the sense lines SL0 and SL1 overlap vertically in the Z direction. In addition, the word select lines WSL0 and WSL1 and the read select lines RSL0 and RSL1 also overlap each other vertically in the Z direction. The memory cell MC and the gate contact GC are disposed at an intersection portion between the bit lines BL0 and BL1 and the word select lines WSL0 and WSL1.

### Operation Modes of Third Embodiment

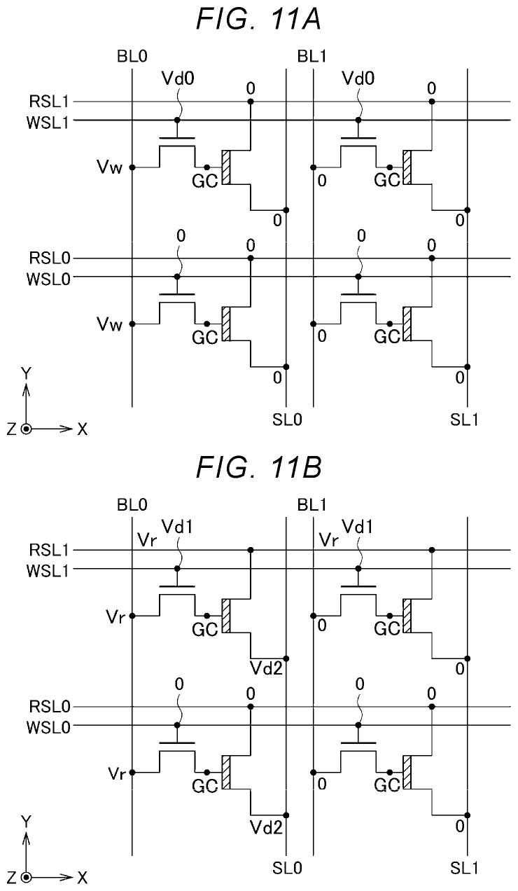

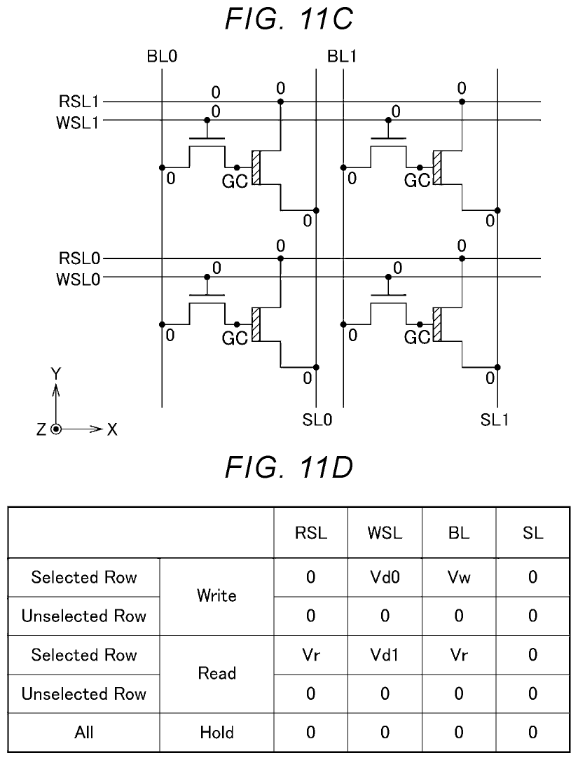

FIG. 11A is a circuit diagram of a write operation. FIG. 11B is a circuit diagram of a read operation. FIG. 11C is a circuit diagram of a hold operation. FIG. 11D is a diagram illustrating operation modes.

During the write operation, a voltage of each part as shown in FIG. 11A is applied in accordance with the operation mode of FIG. 11D. A voltage Vd0 is applied to the word select line WSL1, 0 V is applied to the word line WSL0, 0 V is applied to the read select line RSL1, and 0 V is applied to the read select line RSL0. The write voltage Vw is applied to the bit line BL0, 0 V is applied to the bit line BL1, 0 V is applied to the sense line SL0, and 0 V is also applied to the sense line SL1.

During the read operation, the voltage of each part as shown in FIG. 11B is applied in accordance with the operation mode of FIG. 11D. A voltage Vd1 is applied to the word select line WSL1, 0 V is applied to the word select line WSL0, the read voltage Vr is applied to the read select line RSL1, and 0 V is applied to the read select line RSL0. The read voltage Vr is applied to the bit line BL0, 0 V is applied to the bit line BL1, a voltage Vd2 is applied to the sense line SL0, and 0 V is applied to the sense line SL1.

During the hold operation, a voltage of each part as shown in FIG. 11C is applied in accordance with the operation mode of FIG. 11D. 0 V is applied to the word select lines WSL0 and WSL1, and 0 V is applied to the read select lines RSL0 and RSL1.0 V is applied to the bit lines BL0 and BL1, and 0 V is applied to the sense lines SL0 and SL1.

### Fourth Embodiment: 2T-1FeFET

In a semiconductor memory device according to a fourth embodiment, the ferroelectric memory MTR includes an MFS structure. That is, the ferroelectric memory MTR has a stacked structure of the conductive layer 36/ferroelectric layer 34/semiconductor layer 32. A memory cell of the semiconductor memory device according to the fourth embodiment has the 2T-1FeFET circuit structure and has a combined structure of the source connection configuration in which the source of the ferroelectric memory MTR is connected to the channel of the select transistor MST1, and a gate connection configuration in which the gate of the ferroelectric memory MTR is connected to the channel of the select transistor MST2.

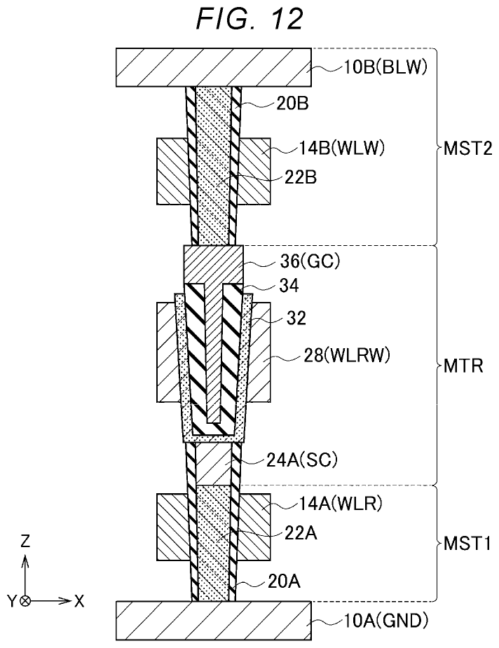

FIG. 12 is a cross-sectional view of the semiconductor memory device according to the fourth embodiment.

As shown in FIG. 12, the semiconductor memory device according to the fourth embodiment includes the ferroelectric memory MTR, the select transistor MST1 connected to the source of the ferroelectric memory MTR, and the select transistor MST2 connected to the gate of the ferroelectric memory MTR.

As shown in FIG. 12, the ferroelectric memory MTR includes the conductive layer 24A extending in the Z direction and having a cylindrical shape, the semiconductor layer 32 in contact with the conductive layer 24A and extending in the radial direction of the cylindrical shape and in the Z direction, the ferroelectric layer 34 in contact with the semiconductor layer 32, the conductive layer 36 in contact with the ferroelectric layer 34, and the conductive layer 28 in contact with a plane intersecting the radial direction of a region extending in the Z direction in the semiconductor layer 32. Here, although not shown, the radial diameter R2 of the semiconductor layer 32 is larger than the radial diameter R1 of the conductive layer 24A, which is the same as in the first embodiment.

In addition, as shown in FIG. 12, the select transistor MST1 includes the semiconductor layer 22A extending in the Z direction, the insulating film 20A serving as the gate insulating layer in contact with the semiconductor layer 22A, and the conductive layer 14A in contact with the insulating film 20A and serving as a read line WLR extending in the Y direction perpendicular to the Z direction, and the semiconductor layer 22A and the conductive layer 24A serving as the source electrode of the ferroelectric memory MTR are in contact with each other.

Further, as shown in FIG. 12, the select transistor MST2 includes the semiconductor layer 22B extending in the Z direction, the insulating film 20B serving as the gate insulating layer in contact with the semiconductor layer 22B, and the conductive layer 14B in contact with the insulating film 20B and serving as a write line WLW extending in the Y direction perpendicular to the Z direction, and the semiconductor layer 22B and the conductive layer 36 serving as the gate electrode of the ferroelectric memory are in contact with each other.

### Modification Example of Fourth Embodiment: 2T-1FeFET

A memory cell of a semiconductor memory device according to a modification example of the fourth embodiment, as in the fourth embodiment, also has the 2T-1FeFET circuit structure and has a combined structure of the source connection configuration in which the source of the ferroelectric memory MTR is connected to the channel of the select transistor MST1, and a gate connection configuration in which the gate of the ferroelectric memory MTR is connected to the channel of the select transistor MST2. In the semiconductor memory device according to the modification example of the fourth embodiment, the ferroelectric memory MTR has the MFMIS structure.

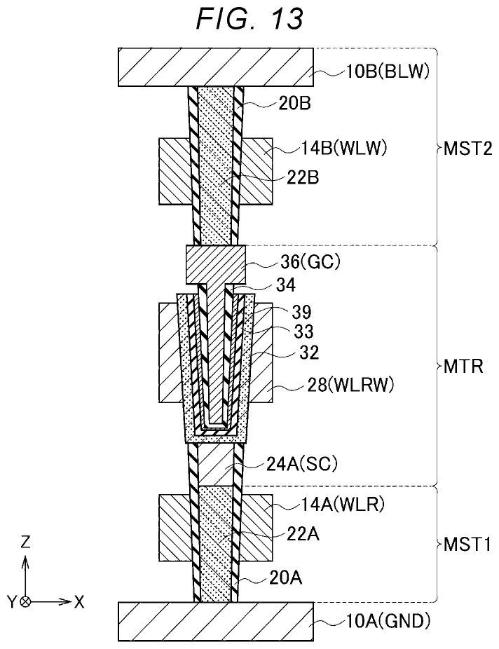

FIG. 13 is a cross-sectional view of the semiconductor memory device according to the modification example of the fourth embodiment.

As shown in FIG. 13, the ferroelectric memory MTR includes the conductive layer 39 and the insulating layer 33 in a stacked structure between the ferroelectric layer 34 and the semiconductor layer 32. That is, the conductive layer 39 is provided between the ferroelectric layer 34 and the semiconductor layer 32 and is in contact with the ferroelectric layer 34, and the insulating layer 33 is provided between the conductive layer 39 and the semiconductor layer 32 and is in contact with the semiconductor layer 32.

The MFMIS structure has a stacked structure of the conductive layer 39 and the insulating layer 33, so that the electric field can be efficiently applied to the ferroelectric layer 34 as compared with the MFS structure of the fourth embodiment. Therefore, the coupling ratio can be reduced, and the stability of spontaneous polarization can be increased. Further, since the electric field can be efficiently applied to the ferroelectric layer 34, the memory window MW can be widened, the storing characteristics can be improved, and the reliability can be increased. Other configurations are the same as those of the semiconductor memory device according to the fourth embodiment.

### Memory Cell Array

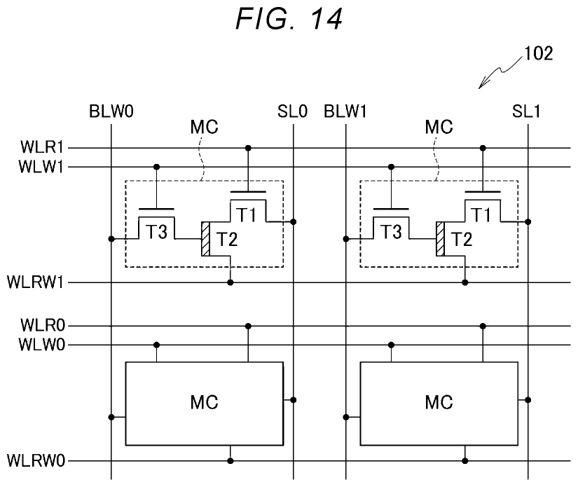

FIG. 14 is a circuit block diagram of the memory cell array of the semiconductor memory device according to the fourth embodiment. The circuit block diagram of the semiconductor memory device according to the modification example of the fourth embodiment is also similarly represented.

In FIG. 14, for simplicity, the ferroelectric memory MTR is represented by T2, and the select transistors MST1 and MST2 are represented by T1 and T3, respectively. The memory cell MC of the semiconductor memory device according to the fourth embodiment has the 2T-1FeFET circuit structure and has a combined structure of the source connection configuration in which the source of the ferroelectric memory T2 is connected to the channel of the select transistor T1, and the gate connection configuration in which the gate of the ferroelectric memory T2 is connected to the channel of the select transistor T3. Such memory cells MC are two-dimensionally disposed.

The gate of the select transistor T1 is connected to the read lines WLR0, WLR1, . . . , and the drain of the select transistor T1 is connected to the sense lines SL0, SL1, . . . . The drain of the ferroelectric memory T2 is connected to the read word lines WLRW0, WLRW1, . . . . The drain of the select transistor T3 is connected to the bit lines BLW0, BLW1, . . . and the gate of the select transistor T3 is connected to the write lines WLW0, WLW1, . . . .

### Method of Manufacturing the Semiconductor Memory Device Having Source Connection Configuration

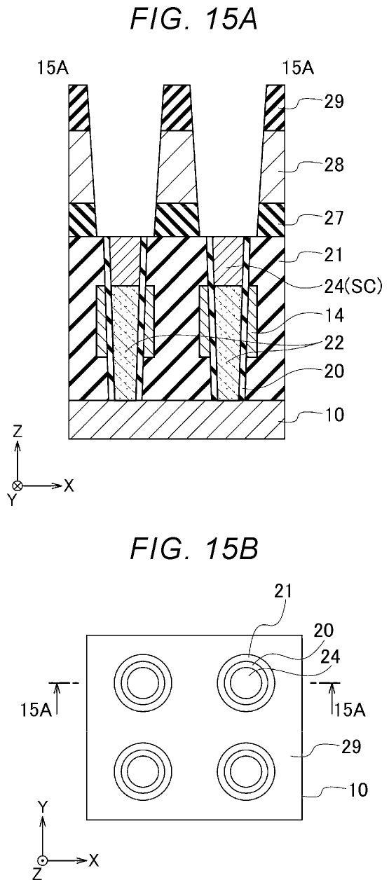

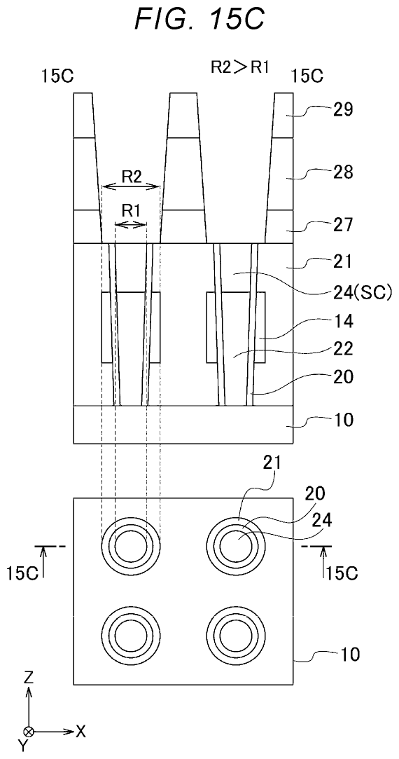

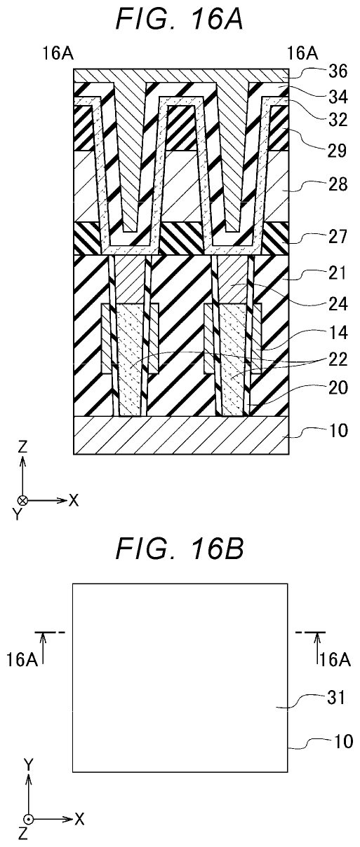

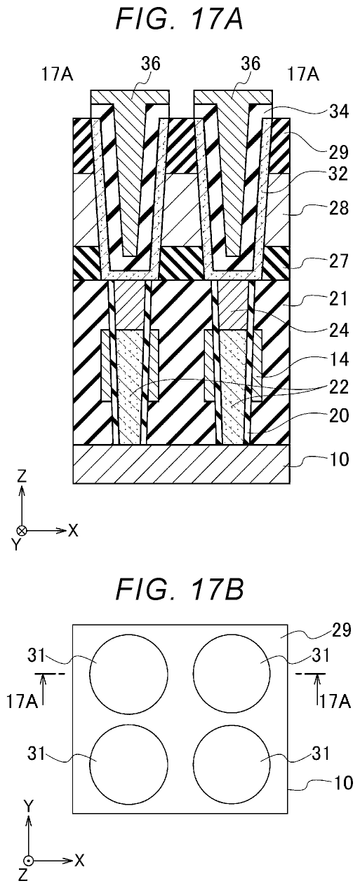

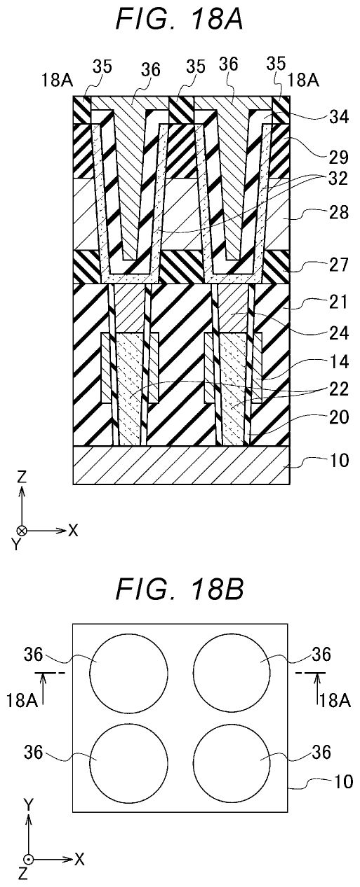

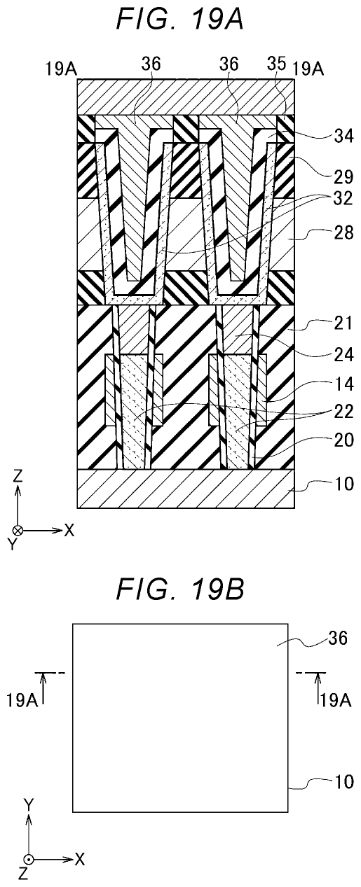

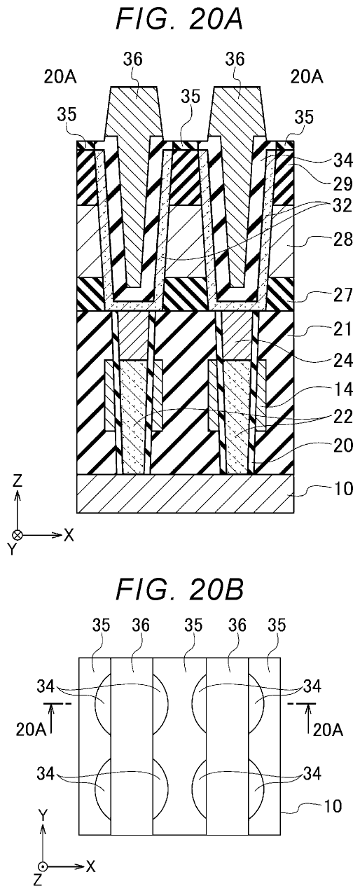

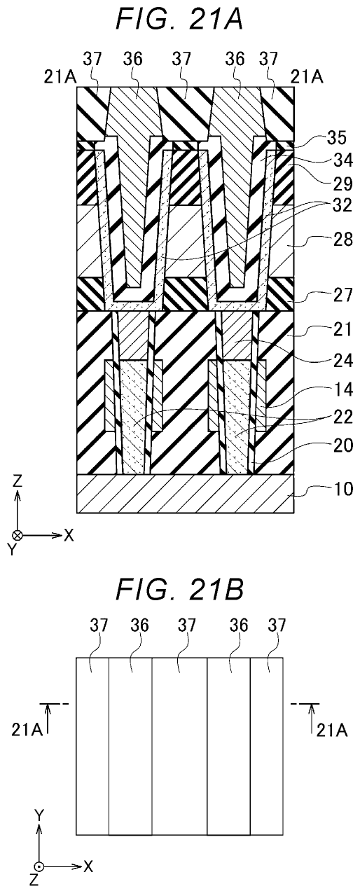

A method of manufacturing the semiconductor memory device having the source connection configuration will be described with reference to FIGS. 15A to 21B. FIG. 15A is a cross-sectional view in an XZ plane taken along line 15A-15A of FIG. 15B, and FIG. 15B is a top view taken along an XY plane. FIG. 15C is a diagram illustrating a size relationship R2>R1 between the radial diameter R2 of the oxide semiconductor layer 32 and the radial diameter R1 of the conductive layer 24 in the semiconductor memory device according to the embodiment of the source connection example. FIG. 16A is a cross-sectional view in an XZ plane taken along line 16A-16A of FIG. 16B, and FIG. 16B is a top view taken along an XY plane. FIG. 17A is a cross-sectional view in an XZ plane taken along line 17A-17A of FIG. 17B, and FIG. 17B is a top view taken along an XY plane. FIG. 18A is a cross-sectional view in an XZ plane taken along line 18A-18A of FIG. 18B, and FIG. 18B is a top view taken along an XY plane. FIG. 19A is a cross-sectional view in an XZ plane taken along line 19A-19A of FIG. 19B, and FIG. 19B is a top view taken along an XY plane. FIG. 20A is a cross-sectional view in an XZ plane taken along line 20A-20A of FIG. 20B, and FIG. 20B is a top view taken along an XY plane. FIG. 21A is a cross-sectional view in an XZ plane taken along line 21A-21A of FIG. 21B, and FIG. 21B is a top view taken along an XY plane.
(A) First, after the select transistor MST is formed, the select transistor MST is flattened through a chemical mechanical polishing (CMP) technique, and an insulating layer 27, the conductive layer 28, and an insulating layer 29 are sequentially deposited on the conductive layer 24 serving as the source electrode of the select transistor MST in the Z direction by using a chemical vapor deposition (CVD) technique. Next, as shown in FIGS. 15A and 15B, the insulating layer 29, the conductive layer 28, and the insulating layer 27 are removed in a cylindrical shape by using a reactive ion etching (RIE) technique, and the conductive layer 24 is exposed at a bottom portion of a cylindrical groove. FIG. 15C is a diagram illustrating the size relationship R2>R1 between the radial diameter R2 of the oxide semiconductor layer 32 and the radial diameter R1 of the conductive layer 24. The radial diameter R2 of the oxide semiconductor layer 32 is larger than the radial diameter R1 of the conductive layer.
(B) Next, as shown in FIGS. 16A and 16B, the oxide semiconductor layer 32 such as IGZO and the ferroelectric layer 34 such as HZO are formed in the cylindrical groove through an atomic layer deposition (ALD) technique, and the conductive layer 36 is further formed. Here, the semiconductor layer 32 is formed of an oxide semiconductor layer such as InGaZnO or InO. The ferroelectric layer 34 may have, for example, a stacked structure of ZrO₂/HfZrO₂/ZrO₂. The film of ZrO₂/HfZrO₂/ZrO₂ using a ZrO₂ layer as a seed layer is formed through the ALD method, and then crystallization annealing of a ferroelectric film is performed through rapid thermal annealing (RTA). For example, annealing is performed in an ozone (O₃) atmosphere in order to reduce oxygen vacancies after film formation.
(C) Next, as shown in FIGS. 17A and 17B, the conductive layer 36, the ferroelectric layer 34, and the oxide semiconductor layer 32 are patterned and removed through lithography and RIE techniques.
(D) Next, as shown in FIGS. 18A and 18B, an insulating layer 35 is deposited and flattened using the CMP technique, and the surface of the conductive layer 36 is exposed.
(E) Next, as shown in FIGS. 19A and 19B, the conductive layer 36 is formed on the device surface.
(F) Next, as shown in FIGS. 20A and 20B, the conductive layer 36 is patterned and processed to form a stripe shape extending in the Y direction through the lithography and RIE techniques.
(G) Next, as shown in FIGS. 21A and 21B, an insulating layer 37 is formed on the device surface and flattened.

### Method of Manufacturing the Semiconductor Memory Device Having a Gate Connection Configuration

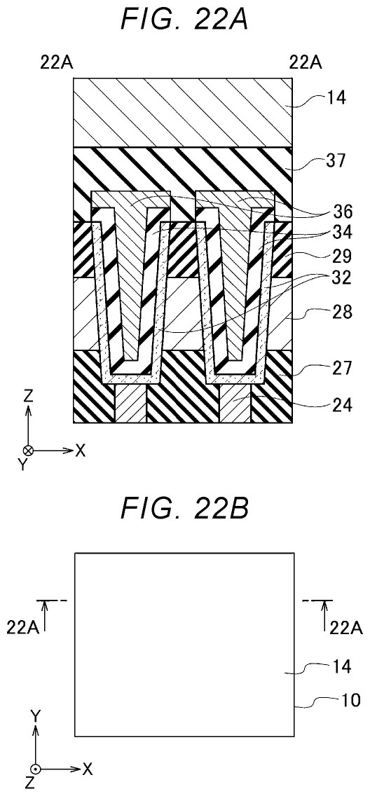

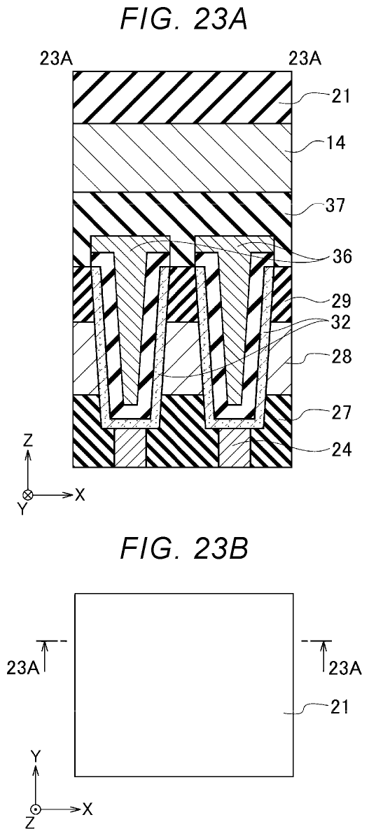

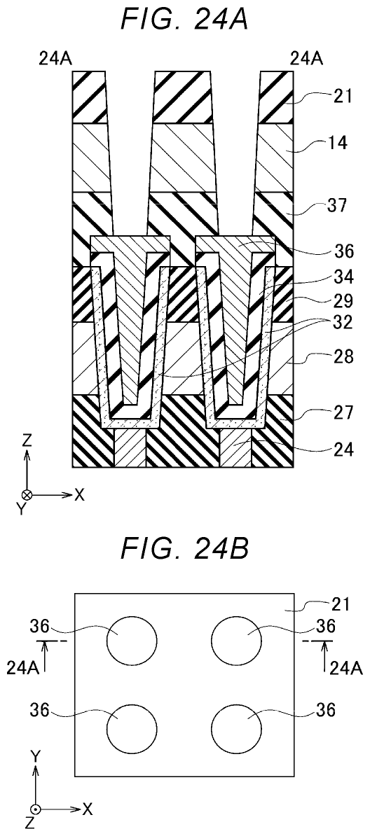

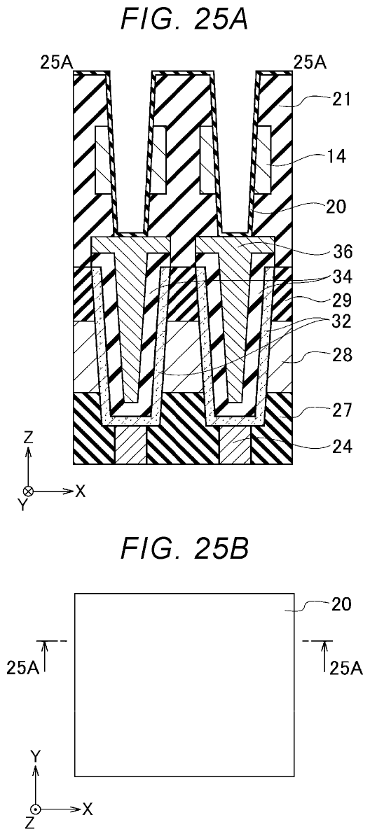

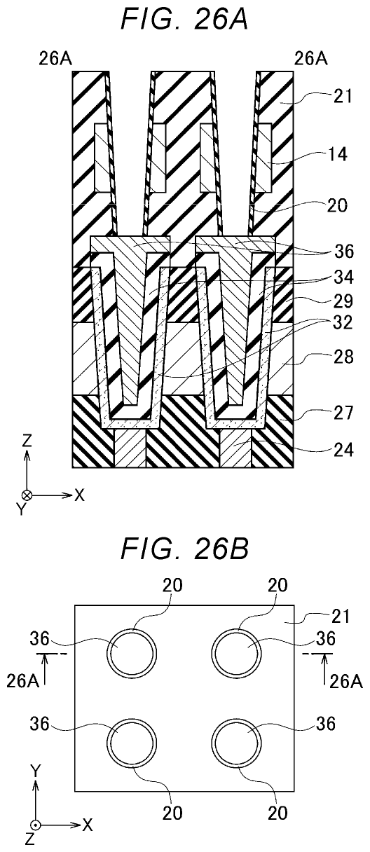

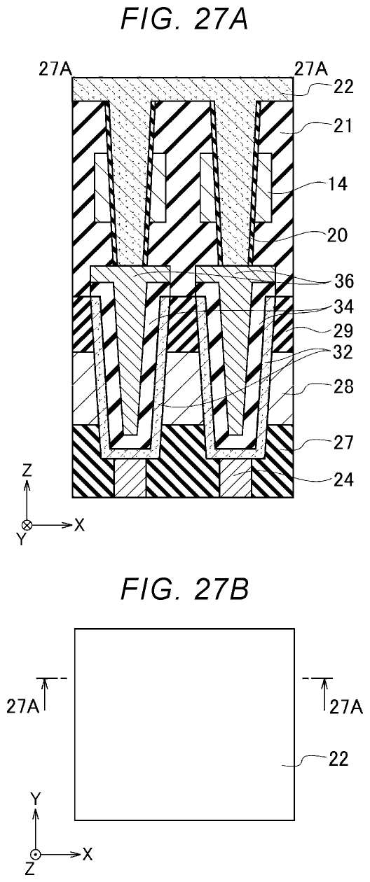

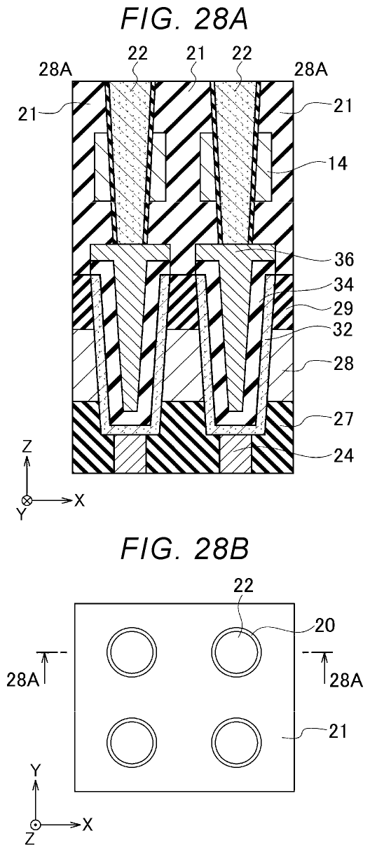

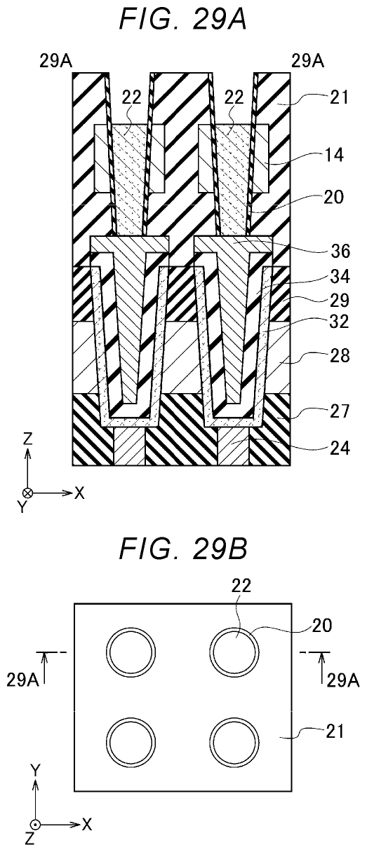

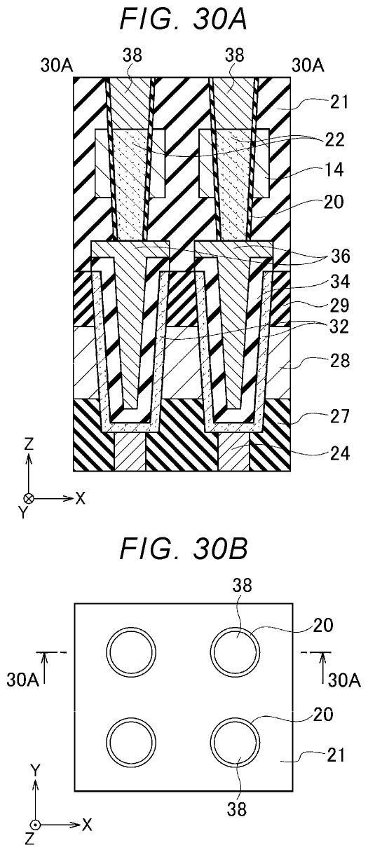

A method of manufacturing the semiconductor memory device having the gate connection configuration will be described with reference to FIGS. 22A to 30B. FIG. 22A is a cross-sectional view in an XZ plane taken along line 22A-22A of FIG. 22B, and FIG. 22B is a top view taken along an XY plane. FIG. 23A is a cross-sectional view in an XZ plane taken along line 23A-23A of FIG. 23B, and FIG. 23B is a top view taken along an XY plane. FIG. 24A is a cross-sectional view in an XZ plane taken along line 24A-24A of FIG. 24B, and FIG. 24B is a top view taken along an XY plane. FIG. 25A is a cross-sectional view in an XZ plane taken along line 25A-25A of FIG. 25B, and FIG. 25B is a top view taken along an XY plane. FIG. 26A is a cross-sectional view in an XZ plane taken along line 26A-26A of FIG. 26B, and FIG. 26B is a top view taken along an XY plane. FIG. 27A is a cross-sectional view in an XZ plane taken along line 27A-27A of FIG. 27B, and FIG. 27B is a top view taken along an XY plane. FIG. 28A is a cross-sectional view in an XZ plane taken along line 28A-28A of FIG. 28B, and FIG. 28B is a top view taken along an XY plane. FIG. 29A is a cross-sectional view in an XZ plane taken along line 29A-29A of FIG. 29B, and FIG. 29B is a top view taken along an XY plane. FIG. 30A is a cross-sectional view in an XZ plane taken along line 30A-30A of FIG. 30B, and FIG. 30B is a top view taken along an XY plane.
(A) First, as shown in FIGS. 22A and 22B, after the ferroelectric memory MTR is formed, the insulating layer 37 and the conductive layer 14 are sequentially deposited on the conductive layer 36 serving as the gate electrode of the ferroelectric memory MTR in the Z direction by using the CVD technique. Next, the conductive layer 14 serving as the read select line RSL is patterned in a stripe shape in the X direction by using the RIE technique.
(B) Next, as shown in FIGS. 23A and 23B, an insulating layer 21 is deposited on the device surface in the Z direction by using the CVD technique.
(C) Next, as shown in FIGS. 24A and 24B, the insulating layer 21, the conductive layer 14, and the insulating layer 37 are removed to form a cylindrical shape by using the RIE technique, and the conductive layer 36 is exposed at the bottom portion of the cylindrical groove.
(D) Next, as shown in FIGS. 25A and 25B, the insulating film 20 serving as the gate insulating layer of the select transistor MST is formed in the cylindrical groove through the ALD technique.
(E) Next, as shown in FIGS. 26A and 26B, the insulating film 20 on the device surface and the bottom portion of the cylindrical groove is removed by using the RIE technique.
(F) Next, as shown in FIGS. 27A and 27B, the semiconductor layer 22 is deposited on the cylindrical groove and the device surface through the ALD technique.
(G) Next, as shown in FIGS. 28A and 28B, the device surface is flattened by using the CMP technique.
(H) Next, as shown in FIGS. 29A and 29B, the semiconductor layer 22 is removed to a predetermined depth by using a wet etching technique. The etching depth is preferably such that the exposed surface of the semiconductor layer 22 is substantially flush with the conductive layer 14.
(I) Next, as shown in FIGS. 30A and 30B, the conductive layer 38 is embedded into the etching groove by using the CVD technique, and the device surface is flattened by using the CMP technique. A doped polysilicon layer may be used instead of the conductive layer 38.

In the above description, the insulating layers 21, 27, 29, 35, and 37 contain at least one material selected from the group consisting of aluminum oxide (AlOₓ), zirconium oxide (ZrOₓ), silicon nitride (SiNₓ), and silicon oxide (SiOₓ).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a ferroelectric memory that includes
a first conductive layer extending in a first direction and having a cylindrical shape and an upper surface that has a diameter R1,
a first semiconductor layer extending in the first direction and having a cylindrical base portion in contact with the upper surface of the first conductive layer, the cylindrical base portion extending further in a radial direction than the upper surface of the first conductive layer such that a diameter R2 thereof is greater than the diameter R1,
a ferroelectric layer extending in the first direction and surrounded by the first semiconductor layer,
a second conductive layer extending in the first direction and surrounded by and in contact with the ferroelectric layer, and
a third conductive layer in contact with an outer periphery of the first semiconductor layer.

2. The semiconductor memory device according to claim 1, further comprising:
a first select transistor,
wherein the first select transistor includes
a second semiconductor layer extending in the first direction,
an insulating film in contact with the second semiconductor layer, and
a fourth conductive layer in contact with the insulating film and extending in a second direction perpendicular to the first direction, and
the second semiconductor layer and the first conductive layer are in contact with each other.

3. The semiconductor memory device according to claim 2, further comprising:
a second select transistor,
wherein the second select transistor includes
a third semiconductor layer extending in the first direction,
an insulating film in contact with the third semiconductor layer, and
a fifth conductive layer in contact with the insulating film and extending in the second direction perpendicular to the first direction, and
the third semiconductor layer and the second conductive layer are in contact with each other.

4. The semiconductor memory device according to claim 2, wherein the insulating film contains at least one element selected from the group consisting of silicon (Si), silicon nitride (SiN), germanium (Ge), aluminum (Al), hafnium (Hf), zirconium (Zr), lanthanum (La), niobium (Nb), yttrium (Y), tantalum (Ta), vanadium (V), and magnesium (Mg), and oxygen.

5. The semiconductor memory device according to claim 2, wherein
the ferroelectric memory further includes a sixth conductive layer and an insulating layer in a stacked structure between the ferroelectric layer and the first semiconductor layer, and
the sixth conductive layer is in contact with the ferroelectric layer, and the insulating layer is in contact with the first semiconductor layer.

6. The semiconductor memory device according to claim 5, further comprising:
a second select transistor that includes
a third semiconductor layer extending in the first direction,
an insulating film in contact with the third semiconductor layer, and
a seventh conductive layer in contact with the insulating film and extending in the second direction,
wherein the third semiconductor layer and the second conductive layer are in contact with each other.

7. The semiconductor memory device according to claim 1, wherein
the second conductive layer has a cylindrical shape that extends in the first direction, and the ferroelectric layer surrounds an outer periphery and a bottom of the second conductive layer, and
a portion of the first semiconductor layer that extends in the first direction surrounds an outer periphery of the ferroelectric layer and the base cylindrical portion of the first semiconductor layer covers a bottom of the ferroelectric layer.

8. The semiconductor memory device according to claim 1, wherein the first semiconductor layer includes an oxide semiconductor layer.

9. The semiconductor memory device according to claim 8, wherein the oxide semiconductor layer contains at least one element selected from the group consisting of indium (In), gallium (Ga), zinc (Zn), tin (Sn), tungsten (W), titanium (Ti), and tantalum (Ta).

10. The semiconductor memory device according to claim 8, wherein the oxide semiconductor layer contains indium oxide and gallium oxide, indium oxide and zinc oxide, or indium oxide and tin oxide.

11. The semiconductor memory device according to claim 8, wherein the oxide semiconductor layer contains titanium oxide (TiO) or tungsten oxide (WO).

12. The semiconductor memory device according to claim 11, wherein the ferroelectric layer has a stacked structure of ZrO₂/HfZrO₂/ZrO₂.

13. The semiconductor memory device according to claim 1, wherein the ferroelectric layer includes an oxide layer containing, as a main component, hafnium (Hf), or hafnium (Hf) and zirconium (Zr).

14. The semiconductor memory device according to claim 1, wherein the first conductive layer contains at least one material selected from the group consisting of tungsten (W), titanium (Ti), titanium nitride (TiN), molybdenum (Mo), cobalt (Co), tantalum (Ta), ruthenium (Ru), iridium (Ir), and impurity-doped silicon.

15. A semiconductor memory device comprising:
a ferroelectric memory that includes
a first conductive layer,
a first semiconductor layer extending in the first direction and having a cylindrical base portion in contact with the first conductive layer,
a ferroelectric layer extending in the first direction surrounded by the first semiconductor layer,
a second conductive layer extending in the first direction and surrounded by and in contact with the ferroelectric layer, and
a third conductive layer in contact with an outer periphery of the first semiconductor layer,
wherein the first conductive layer has a cylindrical base portion that has a larger diameter than and is in contact with the cylindrical base portion of the first semiconductor.

16. The semiconductor memory device according to claim 15, wherein the first conductive layer further has a portion extending in the first direction and surrounding an outer periphery of the first semiconductor layer below the third conductive layer.

17. The semiconductor memory device according to claim 16, further comprising:
a first select transistor,
wherein the first select transistor includes
a second semiconductor layer extending in the first direction,
an insulating film in contact with the second semiconductor layer, and
a fourth conductive layer in contact with the insulating film and extending in a second direction perpendicular to the first direction, and
the second semiconductor layer and the first conductive layer are in contact with each other.

18. A method of manufacturing a semiconductor memory device having a plurality of memory cells, each of the memory cells including a ferroelectric memory and a select transistor that shares an electrode with the ferroelectric memory, the method comprising:
on top of a first conductive layer having a cylindrical shape, sequentially forming a first insulating layer, a second conductive layer, and a second insulating layer;
etching through the first insulating layer, the second conductive layer, and the second insulating layer in a first direction to form a first groove that exposes an entire upper surface of the first conductive layer through the first groove;
sequentially forming an oxide semiconductor layer and a ferroelectric layer in the first groove using an atomic layer deposition method;
forming a third conductive layer on the ferroelectric layer; and
patterning the third conductive layer, the ferroelectric layer, and the oxide semiconductor layer to form the ferroelectric memory of one of the memory cells,
wherein a diameter of the first conductive layer at the exposed surface thereof is smaller than a diameter of a bottom portion of the first groove.

19. The method of manufacturing the semiconductor memory device according to claim 18, wherein the first conductive layer is an electrode that is shared by the ferroelectric memory and the select transistor.

20. The method of manufacturing the semiconductor memory device according to claim 18, further comprising:
sequentially forming a third insulating layer, a fourth conductive layer, and a fourth insulating layer on the third conductive layer;
etching through the third insulating layer, the fourth conductive layer, and the fourth insulating layer in the first direction to form a second groove that exposes an upper surface of the third conductive layer;
forming an insulating film on surfaces exposed by the second groove using an atomic layer deposition method;
removing the insulating film at the bottom portion of the second groove and depositing a semiconductor layer on the insulating film and on the bottom surface of the second groove using another atomic layer deposition method; and
etching a part of the semiconductor layer in the second groove to form a third groove and depositing a fifth conductive layer in the third groove,
wherein the fifth conductive layer is an electrode that is shared by the ferroelectric memory and the select transistor.
